(19) United States
(12) Patent Application Publication
(10) Pub. No.: US 2026/0090367 A1
(43) Pub. Date: Mar. 26, 2026

(54) SEMICONDUCTOR DIE, SEMICONDUCTOR PACKAGE AND MANUFACTURING METHOD OF SEMICONDUCTOR DIE

(71) Applicant: Taiwan Semiconductor Manufacturing Company, Ltd., Hsinchu (TW)

(72) Inventors: Yi-Chen Li, Taichung City (TW); Jen-Yuan Chang, Hsinchu City (TW)

(73) Assignee: Taiwan Semiconductor Manufacturing Company, Ltd., Hsinchu (TW)

(21) Appl. No.: 18/890,763

(22) Filed: Sep. 20, 2024

(51) Int. Cl. H01L 23/522; H01L 23/528; H01L 23/532

(52) U.S. Cl. CPC H10W 20/496; H10W 20/435; H10W 20/4405; H10W 20/4421

(57) ABSTRACT

A semiconductor die including a semiconductor substrate, an interconnect structure, a capacitor structure, a redistribution layer and a bonding structure is provided. The interconnect structure is disposed on the semiconductor substrate. The capacitor structure is disposed on the interconnect structure. The redistribution layer is disposed on and electrically connected to the interconnect structure. The bonding conductor is electrically and physically in contact with the capacitor structure at a sidewall of the bonding conductor, wherein the redistribution layer is located at a lower level than the bonding conductor.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed and greater bandwidth, as well as lower power consumption and latency has grown recently, there has grown a need for smaller and more creative packaging techniques of semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1I illustrate schematic cross-sectional views of various stages of a manufacturing method of a semiconductor die, in accordance with some embodiments of the present disclosure.

FIG. 2 is a schematic cross-sectional view of a semiconductor die in accordance with some alternative embodiments of the present disclosure.

FIG. 3 is a schematic cross-sectional view of a semiconductor die in accordance with some alternative embodiments of the present disclosure.

FIG. 4 is a schematic cross-sectional view of a semiconductor die in accordance with some alternative embodiments of the present disclosure.

FIG. 5A to FIG. 5H illustrate schematic cross-sectional views of various stages of a manufacturing method of a semiconductor package, in accordance with some embodiments of the present disclosure.

FIG. 6 is a schematic top view of a portion of the semiconductor die in the semiconductor package shown in FIG. 5H.

FIG. 7 is a schematic cross-sectional view of a semiconductor package in accordance with some alternative embodiments of the present disclosure.

FIG. 8 is a schematic cross-sectional view of a semiconductor package in accordance with some alternative embodiments of the present disclosure.

FIG. 9 is a schematic cross-sectional view of a semiconductor package in accordance with some alternative embodiments of the present disclosure.

FIG. 10 is a schematic cross-sectional view of a semiconductor package in accordance with some alternative embodiments of the present disclosure.

FIG. 11 is a schematic cross-sectional view of a semiconductor package in accordance with some alternative embodiments of the present disclosure.

FIG. 12 is a schematic cross-sectional view of a semiconductor package in accordance with some alternative embodiments of the present disclosure.

FIG. 13 is a schematic cross-sectional view of a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, and the like, may be used herein for ease of description to describe similar or different element(s) or feature(s) as illustrated in the figures, and may be used interchangeably depending on the order of the presence or the contexts of the description.

As used herein, “about,” “approximately,” or “substantially” shall generally mean within 20 percent, or within 10 percent, or within 5 percent, or within 3 percent, or within 1 percent of a given value or range. Numerical quantities given herein are approximate, meaning that the term “about,” “approximately,” or “substantially” can be inferred if not expressly stated.

It would be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor package and a manufacturing method thereof, and is not intended to limit the scope of the disclosure. In some embodiments, the semiconductor package may be or include a part of a system-on-integrated-circuit (SoIC) package, an integrated fan-out (InFO) package, a chip-on wafer (CoW) package, a system-on-wafer (SoW), a chip-on wafer-on-substrate (CoWoS) package, a package-on-package (PoP), an InFO package with POP, a wafer-level package (WLP), a device or package of three-dimensional fabric (3Dfabric), or the like.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

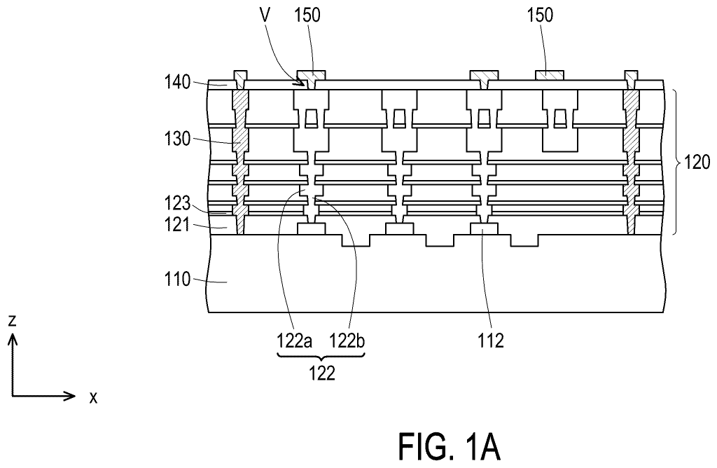

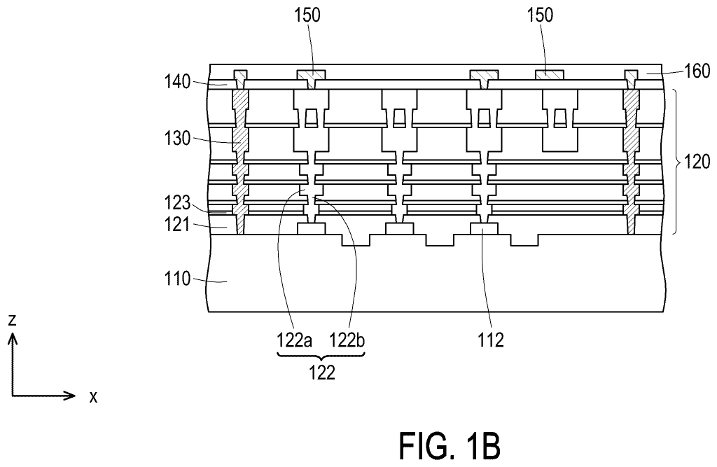

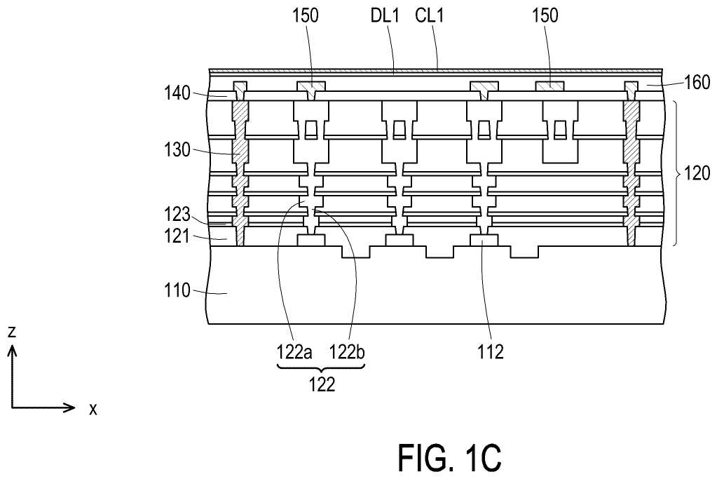

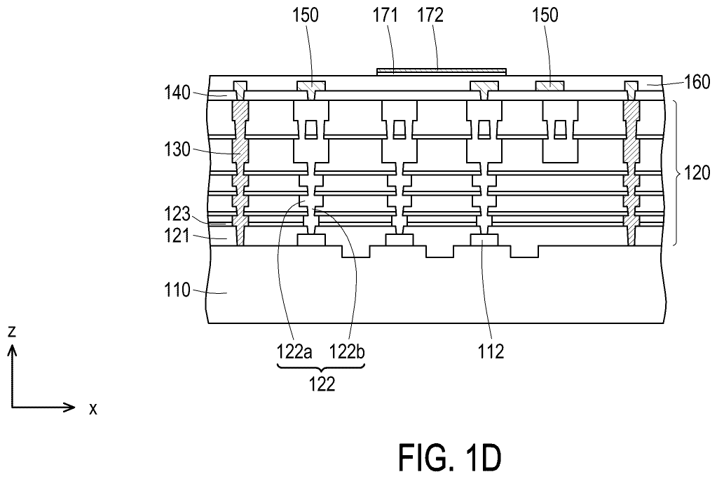

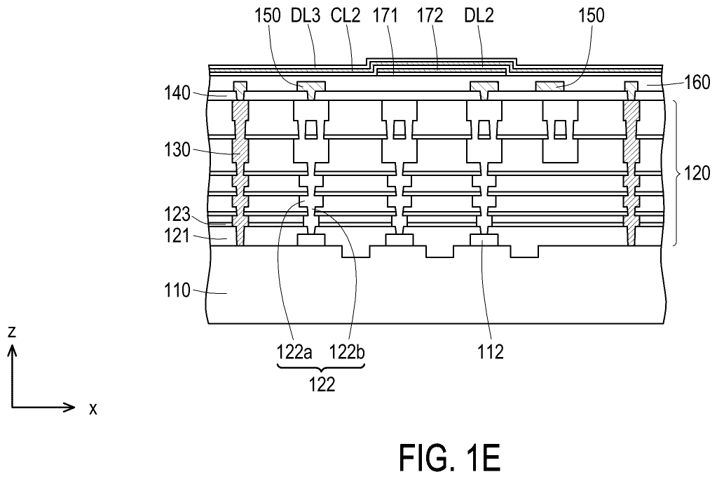

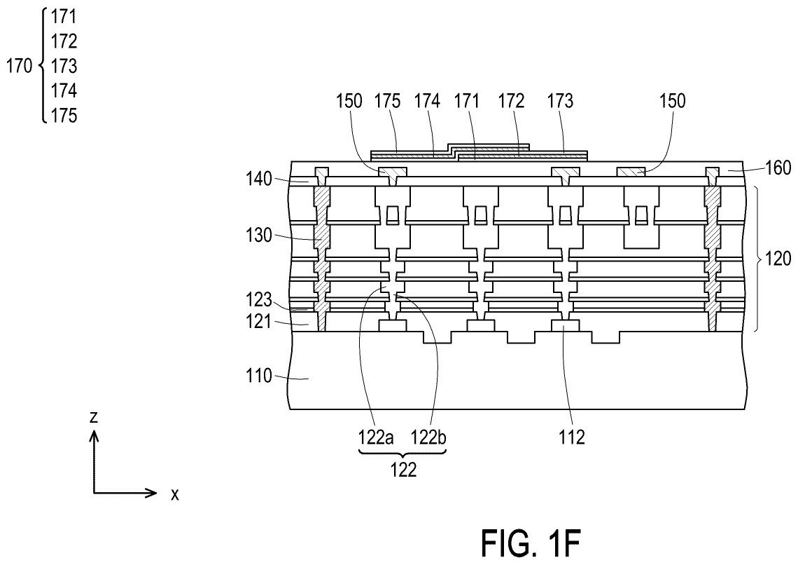

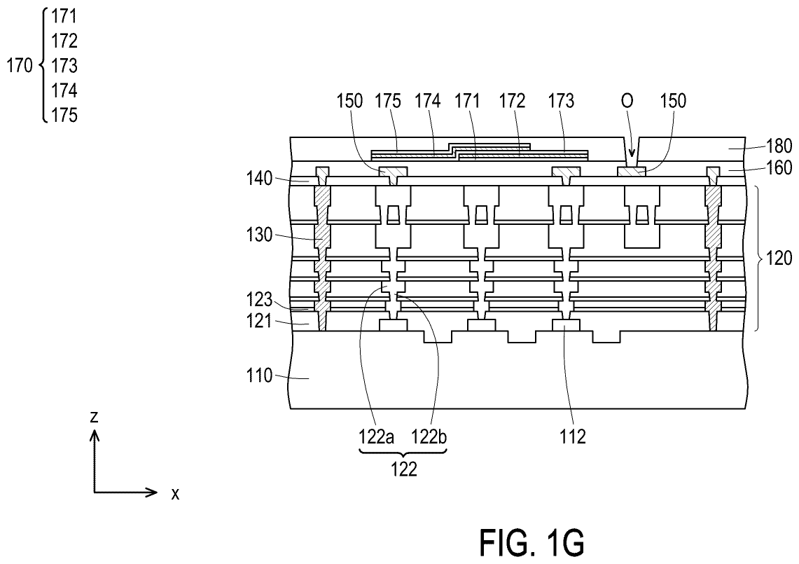

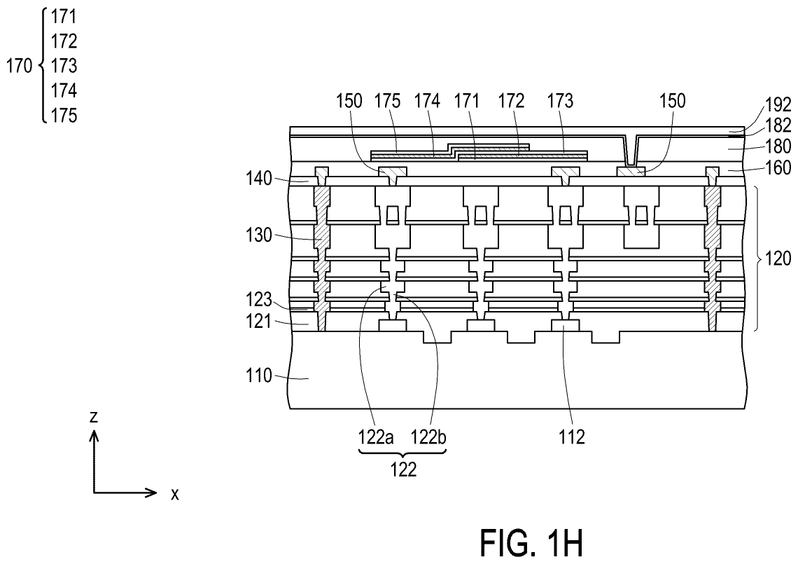

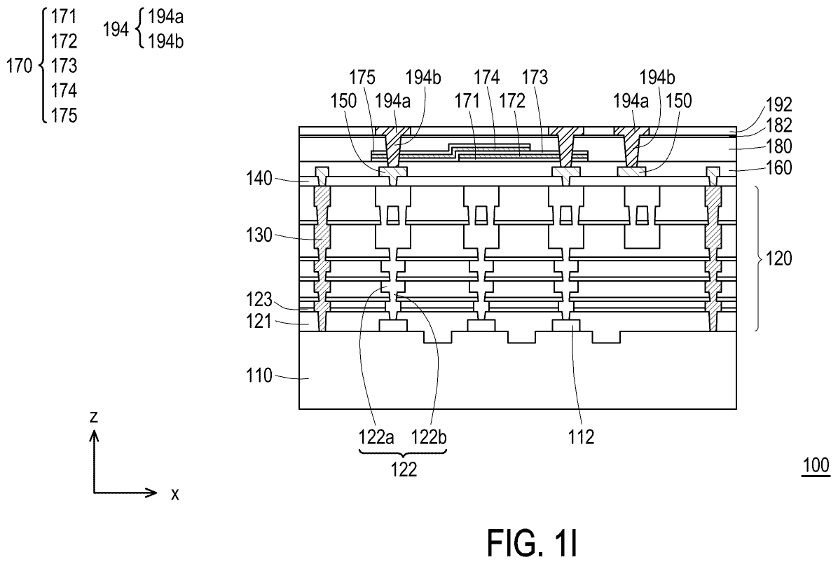

FIG. 1A to FIG. 1I illustrate schematic cross-sectional views of various stages of a manufacturing method of a semiconductor die 100, in accordance with some embodiments of the present disclosure.

Referring to FIG. 1A, a semiconductor substrate 110 is provided. In some embodiments, the semiconductor substrate 110 serves as a carrier for the following layers/components to be formed or disposed thereon. In some embodiments, the semiconductor substrate 110 includes Si, Ge, SiGe, SiC, or other proper semiconductor materials. The semiconductor substrate 110 may be a bulk substrate or constructed as a semiconductor on an insulator (SOI) substrate. The semiconductor substrate 110 may include a redistribution layer (RDL), a dielectric structure, or a combination thereof. The RDL may include conductive layers and/or conductive vias. The semiconductor substrate 110 may include one or more devices 112 adjacent to a top surface of the semiconductor substrate 110. The devices 112 may include integrated circuit devices such as transistors, diodes, resistors, capacitors, and/or the like.

Continued referring to FIG. 1A, an interconnection structure 120 is formed on the semiconductor substrate 110. In some embodiments, the interconnection structure 120 includes a plurality of dielectric layers 121, a plurality of conductive patterns 122, and a plurality of etch stop layers 123. In some embodiments, referring to FIG. 1A, the dielectric layers 121 and the etch stop layers 123 are alternately formed along a direction Z perpendicular to the top surface of the semiconductor substrate 110, and the conductive patterns 122 are embedded in the dielectric layers 121 and the etch stop layers 123. As shown in FIG. 1A, the conductive patterns 122 include routing traces 122a extending horizontally along a direction X perpendicular to the direction Z in the dielectric layers 121, and vias 122b vertically penetrating through the dielectric layers 121 to establish electrical connection between the above and underlying routing traces 122a and to the devices 110. That is, the interconnection structure 120 provides redistributing functions for routing, relocating or redistribution the electrical connection paths for the devices 110.

Further, a seal ring 130 is formed penetrating the interconnection structure 120. As shown in FIG. 1A, the seal ring 130 extends vertically through the dielectric layers 121 and the etch stop layers 123. In some embodiments, the seal ring 130 is formed by one or more materials the same as the material(s) of the conductive patterns 122. The seal ring 130 functions as a structural supportive element for reinforcing the structural rigidity during dicing or pruning. In some embodiments, the seal ring 130 is an electrically floating element. It is understood that the numbers and configurations of the dielectric layers 121, the etch stop layers 123 and the conductive patterns 122 are merely exemplary and not intended to limit the scope of this disclosure.

Continued referring to FIG. 1A, a passivation layer 140 is formed on the interconnection structure 120. The material of the passivation layer 140 may include silicon oxide, silicon nitride, silicon oxynitride, undoped silicon glass (USG), or the like. Further, referring to FIG. 1A, a redistribution layer 150 is formed penetrating the passivation layer 140 to electrically connect with the interconnection structure 120. In detail, as shown in FIG. 1A, the redistribution layer 150 has vias V penetrating the passivation layer 140 to electrically connect with the interconnection structure 120. In some embodiments, the redistribution layer 150 includes conductive patterns, such as conductive pads and/or conductive wirings. The conductive patterns of the redistribution layer 150 may have a pitch or a line/spacing (L/S) different from that of the conductive patterns 122 of the interconnection structure 120. In some embodiments, the material of the redistribution layer 150 includes aluminum, aluminum copper, copper, or any other suitable conductive materials. In certain embodiments, the redistribution layer 150 includes aluminum pads, or copper-doped aluminum pads, wherein a doping concentration of copper is about 0.001% to about 50%. In an embodiment, the doping concentration of copper is about 0.5%.

Referring to FIG. 1B, a gap-filling dielectric layer 160 is formed on the passivation layer 140 and covers the redistribution layer 150. In some embodiments, the gap-filling dielectric layer 160 fills the gaps between the conductive patterns of the redistribution layer 150 for providing a substantially planar top surface. In some embodiments, a planarization process is performed on the gap-filling dielectric layer 160 to provide the substantially planar top surface. The planarization process may include performing a chemical mechanical polishing (CMP) process. In some embodiments, the gap-filling dielectric layer 160 is formed by chemical vapor deposition (CVD) (such as plasma enhanced CVD, high-density plasma CVD (HDPCVD), or metalorganic CVD (MOCVD)), or physical vapor deposition (PVD). In some embodiments, the material of the gap-filling dielectric layer 160 may include dielectric materials, such as SiO, SiN, SiON.

After forming the gap-filling dielectric layer 160, a capacitor structure 170 is formed on the gap-filling dielectric layer 160. The formation of the capacitor structure 170 will be described in details below with reference to FIG. 1C to FIG. 1F.

Referring to FIG. 1C, a dielectric material layer DL1 and a conductive material layer CL1 are formed over the gap-filling dielectric layer 160 in sequence. In some embodiments, the dielectric material layer DL1 is made of a high dielectric constant (high-k) dielectric materials (e.g. the dielectric constant (k) is in a range from about 10 to about 20) including oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, or another applicable material. In some embodiments, the dielectric material layer DL1 is formed by performing a plasma enhanced CVD process, a low pressure CVD process, an atomic layer deposition (ALD) process, a molecular beam deposition (MBD) or another applicable process. In some embodiments, the conductive material layer CL1 is made of metals. In some embodiments, the conductive material layer CL1 is made of aluminum, copper, tungsten, titanium, tantalum, titanium nitride, tantalum nitride, or another applicable material. In some embodiments, the conductive material layer CL1 is formed by performing a deposition process (e.g. a CVD process, a PVD process or an ALD process).

Referring to FIG. 1D, the dielectric material layer DL1 and the conductive material layer CL1 are patterned to form a dielectric layer 171 and an electrode layer 172 by using lithography and etching and/or any suitable patterning process. In some embodiments, the dielectric material layer DL1 and the conductive material layer CL1 are patterned in the same patterning process. In some alternative embodiments, the dielectric material layer DL1 and the conductive material layer CL1 are patterned in the different patterning processes. As shown in FIG. 1D, the sidewall of the electrode layer 172 is substantially aligned with the sidewall of the underlying dielectric layer 171.

Referring to FIG. 1E, a dielectric material layer DL2, a conductive material layer CL2 and a dielectric material layer DL3 are formed over the gap-filling dielectric layer 160 in sequence. In some embodiments, the dielectric material layer DL2, the conductive material layer CL2 and the dielectric material layer DL3 are conformally formed over the gap-filling dielectric layer 160 and cover the dielectric layer 171 and the electrode layer 172, as shown in FIG. 1E. The materials and processes used to form the dielectric material layer DL2 and the dielectric material layer DL3 may be similar to, or the same as, those of the dielectric material layer DL1, and the details thereof are not repeated herein. The material and process used to form the conductive material layer CL2 may be similar to, or the same as, those of the conductive material layer CL1, and the details thereof are not repeated herein. The material of the dielectric material layer DL2 may be the same as or different from that of the dielectric material layer DL1. Also, the material of the dielectric material layer DL3 may be the same as or different from that of the dielectric material layer DL2. And, the material of the conductive material layer CL2 may be the same as or different from that of the conductive material layer CL1.

Referring to FIG. 1F, the dielectric material layer DL2, the conductive material layer CL2 and the dielectric material layer DL3 are subsequently patterned to form a dielectric layer 173, an electrode layer 174 and a dielectric layer 175 by using lithography and etching and/or any suitable patterning process, thereby forming the capacitor structure 170. In some embodiments, the conductive material layer CL2 and the dielectric material layer DL3 are patterned in the same patterning process. In some alternative embodiments, the conductive material layer CL2 and the dielectric material layer DL3 are patterned in the different patterning processes. Further, in some embodiments, the dielectric material layer DL2 and the conductive material layer CL2 are patterned in the different patterning processes. As shown in FIG. 1F, the electrode layer 174 partially overlaps the electrode layer 172. The dielectric layer 173 may be positioned between the electrode layer 174 and the electrode layer 172. The sidewall of the electrode layer 172 may be separated from the electrode layer 174 by the dielectric layer 173. In addition, the dielectric layer 175 has a sidewall substantially aligned with the sidewall of the underlying electrode layer 174, and the sidewall of the dielectric layer 173 is staggered with the overlying electrode layer 174 but is substantially aligned with the sidewall of the underlying electrode layer 172.

As shown in FIG. 1F, the capacitor structure 170 includes a metal-insulator-metal (MIM) capacitor comprising the electrode layer 172 as a bottom electrode layer, the dielectric layer 173 as a capacitor dielectric layer, and the electrode layer 174 as a top electrode layer. It is understood that the numbers and configurations of the electrode layers and the dielectric layers of the capacitor structure 170 are merely exemplary and not intended to limit the scope of this disclosure. That is, the aforementioned process for forming the capacitor structure 170 is merely one method of forming the MIM capacitor, and other methods are also fully intended to be included within the scope of the embodiments.

Referring to FIG. 1G, a passivation layer 180 is formed over the gap-filling dielectric layer 160 and covers the capacitor structure 170. The material of the passivation layer 180 may include silicon oxide, silicon nitride, silicon oxynitride, undoped silicon glass (USG), or the like.

Continued referring to FIG. 1G, an opening O is formed through the passivation layer 180 and the gap-filling dielectric layer 160 to expose a portion of the redistribution layer 150. In some embodiments, the opening O in the passivation layer 180 and the gap-filling dielectric layer 160 is formed by any acceptable patterning process. For example, a photoresist is formed and patterned over the passivation layer 180, and one or more etching processes may be utilized to remove portions of the passivation layer 180 and the gap-filling dielectric layer 160 where the opening O is desired. It is noted that the exposed portion of the redistribution layer 150 is used to perform a chip probe (CP) test and/or a wafer acceptance test (WAT). However, the disclosure is not limited thereto. In some alternative embodiments, the formation of the opening O is omitted in the manufacturing method of the semiconductor die 100.

Referring to FIG. 1H, an etch stop layer 182 and a dielectric layer 192 are formed over the passivation layer 140 in sequence. In some embodiments, the dielectric layer 192 is configured to be hybrid-bonded or fusion-bonded to another dielectric layer. In such embodiments, the dielectric layer 192 is referred to as a bonding dielectric layer. In some embodiments, the dielectric layer 192 includes an oxide based layer. In some embodiments, the dielectric layer 192 includes silicon oxide, silicon oxynitride, or any suitable materials configured for hybrid bonding or fusion bonding.

Referring to FIG. 1I, bonding conductors 194 are formed to electrically connect with the redistribution layer 150 and the capacitor structure 170. The material of the bonding conductors 194 may be or include copper or other suitable conductive materials. Furthermore, in some embodiments, each of the bonding conductors 194 may optionally include a barrier layer (not shown) at the outer surface, so as to avoid diffusion of atoms between elements. For example, the material of the barrier layer may be or include tungsten (W), titanium nitride (TiN), titanium (Ti), tantalum (Ta), tantalum nitride (TaN), combinations thereof or other suitable materials. Further, as shown in FIG. 1I, the bonding conductors 194 are formed at a higher level than the redistribution layer 150.

As shown in FIG. 1I, due to the formation of the etch stop layer 182, the bonding conductors 194 each may include a conductive via 194b and a conductive pad 194a wider than the conductive via 194b. Although in FIG. 1I, the bonding conductor 194 is formed as having two portions (i.e., the conductive via 194b and the conductive pad 194a), the disclosure is not limited thereto. In some alternative embodiments, the bonding conductor 194 may be formed as a single portion with a continuous sidewall.

In detail, as shown in FIG. 1I, the conductive pad 194a of each of the bonding conductors 194 is formed being embedded in and physically in contact with the dielectric layer 192; the conductive via 194b of one of the bonding conductors 194 is formed passing through the passivation layer 180, the dielectric layer 173, the electrode layer 172, the dielectric layer 171 and the gap-filling dielectric layer 160 and electrically connected to the redistribution layer 150; and the conductive via 194b of another one of the bonding conductors 194 is formed passing through the passivation layer 180, the dielectric layer 173, the electrode layer 174, the dielectric layer 175 and the gap-filling dielectric layer 160 and electrically connected to the redistribution layer 150. That is, one of the bonding conductors 194 is electrically connected to the electrode layer 172 of the capacitor structure 170 as an electrode connector, and another one of the bonding conductors 194 is electrically connected to the electrode layer 174 of the capacitor structure 170 as another electrode connector. In other words, the electrode layer 172 of the capacitor structure 170 is electrically and physically in contact with the sidewall of one of the bonding conductors 194 (e.g., the sidewall of the conductive via 194b), and the electrode layer 174 of the capacitor structure 170 is electrically and physically in contact with the sidewall of another one of the bonding conductors 194 (e.g., the sidewall of the conductive via 194b). From another point of view, in some embodiments, the capacitor structure 170 laterally surrounds the sidewalls of some of the bonding conductors 194. It is noted that since the bonding conductors 194 made of copper are used as the electrode connectors of the capacitor structure 170, the junction resistance between the capacitor structure 170 and the electrode connectors can be reduced. Thereby, the capacitor efficiency of the capacitor structure 170 is improved. In some embodiments, the junction resistance of the capacitor structure 170 is smaller than the resistance of the passivation layer 180, the gap-filling dielectric layer 160, the passivation layer 140 or the dielectric layer 121, and is larger than or substantially equal to the resistance of the bonding conductor 194, the redistribution layer 150 or the conductive pattern 122.

Further, in some embodiments, the illustrated top surface of the bonding conductor 194 (i.e., the illustrated top surface of the conductive pad 194a) is substantially coplanar to the illustrated top surface of the dielectric layer 192, as shown in FIG. 1I. It is noted that the bonding conductor 194 and the dielectric layer 192 have the illustrated top surfaces with a high degree of coplanarity, which is beneficial for a subsequent process (e.g., a bonding process).

Continued referring to FIG. 1I, a singulation process is performed along the scribe lines such that a plurality of singulated semiconductor dies 100 are formed. It is noted that, the manufacturing process described above is part of a wafer level packaging process, although one singulated semiconductor die 100 is shown in FIG. 1I, those skilled in the art should understand that plural semiconductor dies 100 are obtained after the singulation process. In some embodiments, the singulation process includes a dicing process or a sawing process. In a subsequent process, the singulated semiconductor die 100 may, for example, be disposed onto a package substrate or onto other components based on requirements.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure.

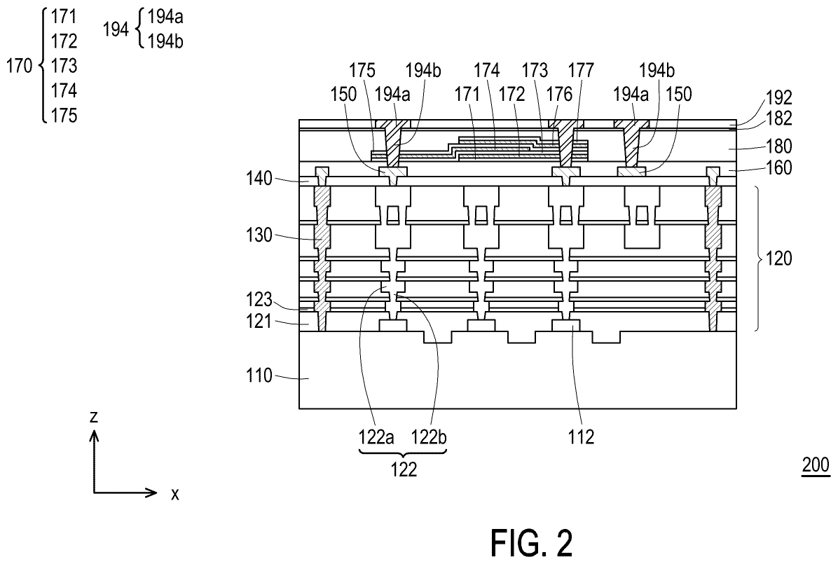

As shown in FIG. 1I, the capacitor structure 170 includes five-layered structure (i.e., IMIMI). However, the invention is not limited thereto. It should be understood that the structure of FIG. 1I is shown for illustrative purpose only, more than five layers may be possible to increase the capacitance of capacitor, or fewer layers may also be possible depending on product requirements. Hereinafter, other embodiments will be described with reference to FIG. 2.

FIG. 2 is a schematic cross-sectional view of a semiconductor die 200 in accordance with some alternative embodiments of the present disclosure. The semiconductor die 200 illustrated in FIG. 2 is similar to the semiconductor die 100 illustrated in FIG. 1I, hence the same reference numerals are used to refer to the same or liked parts, and its detailed description will be omitted herein. The differences between the semiconductor die 200 and the semiconductor die 100 will be described below.

Referring to FIG. 2, in the semiconductor die 200, a capacitor structure 270 includes an electrode layer 176 and a dielectric layer 177 formed over the dielectric layer 175 in sequence. That is, the capacitor structure 270 includes seven-layered structure (i.e., IMIMIMI). In detail, as shown in FIG. 2, in the semiconductor die 200, the electrode layer 176 partially overlaps the electrode layer 174. As shown in FIG. 2, in the semiconductor die 200, the dielectric layer 175 may be positioned between the electrode layer 176 and the electrode layer 174, and the sidewall of the electrode layer 174 may be separated from the electrode layer 176 by the dielectric layer 173. In addition, as shown in FIG. 2, in the semiconductor die 200, the dielectric layer 177 has a sidewall substantially aligned with the sidewall of the underlying electrode layer 176, and the sidewall of the dielectric layer 175 is staggered with the overlying electrode layer 176 but is substantially aligned with the sidewall of the underlying electrode layer 174. Further, as shown in FIG. 2, in the semiconductor die 200, the electrode layer 172 and the electrode layer 176 of the capacitor structure 270 are electrically connected to the same bonding conductor 194; while the electrode layer 174 of the capacitor structure 270 is electrically connected to another one bonding conductor 194.

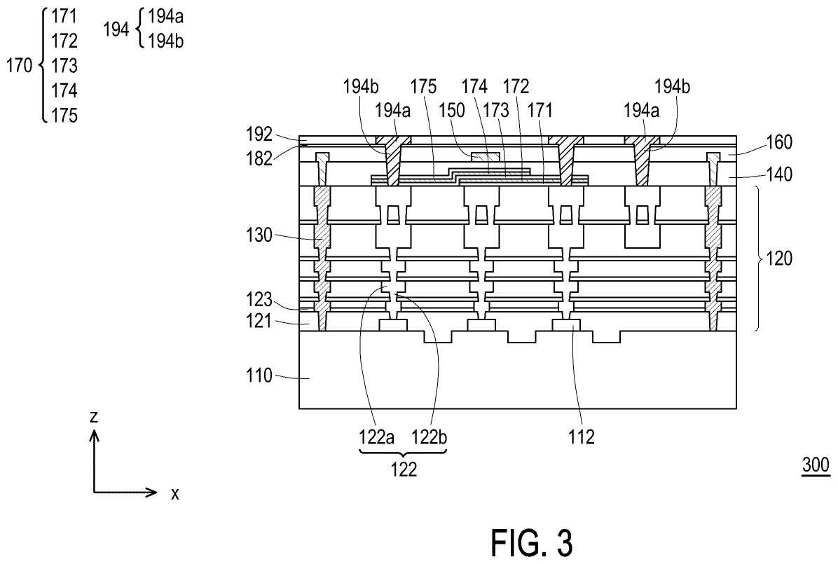

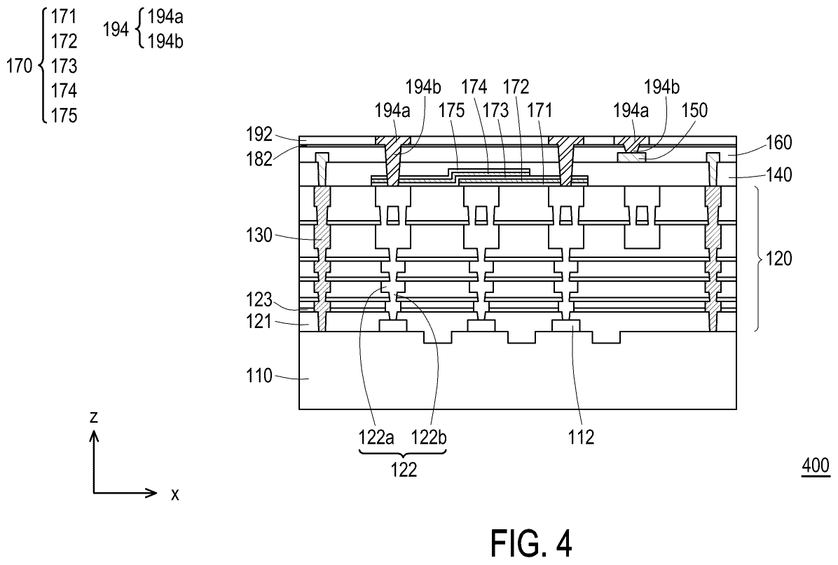

As shown in FIGS. 1A-1I, in the semiconductor die 100, the capacitor structure 170 is formed after the formation of the redistribution layer 150. However, the disclosure is not limited thereto. In some alternative embodiments, the capacitor structure 170 may be formed before the formation of the redistribution layer 150. Hereinafter, other embodiments will be described with reference to FIG. 3 and FIG. 4.

FIG. 3 is a schematic cross-sectional view of a semiconductor die 300 in accordance with some alternative embodiments of the present disclosure. The semiconductor die 300 illustrated in FIG. 3 is similar to the semiconductor die 100 illustrated in FIG. 1I, hence the same reference numerals are used to refer to the same or liked parts, and its detailed description will be omitted herein. The differences between the semiconductor die 300 and the semiconductor die 100 will be described below.

Referring to FIG. 3, in the semiconductor die 300, the capacitor structure 170 is disposed between the interconnection structure 120 and the redistribution layer 150, and is covered by the passivation layer 140. In detail, as shown in FIG. 3, in the semiconductor die 300, the bonding conductors 194, electrically and physically in contact with the capacitor structure 170 and as the electrode connectors of the capacitor structure 170, extend vertically along the direction Z through the gap-filling dielectric layer 160, the passivation layer 140 and the capacitor structure 170, and land on the conductive patterns 122 of the interconnection structure 120. Further, as shown in FIG. 3, in the semiconductor die 300, all of the bonding conductors 194 land on and are physically in contact with the conductive patterns 122 of the interconnection structure 120. However, the disclosure is not limited thereto. In some alternative embodiments, as shown in FIG. 4, in a semiconductor die 400, some of the bonding conductors 194 land on and are physically in contact with the redistribution layer 150. In detail, as shown in FIG. 4, in the semiconductor die 400, the bonding conductor 194 not used as the electrode connector of the capacitor structure 170 vertically penetrates through the gap-filling dielectric layer 160 to establish electrical connection with the redistribution layer 150. Since the semiconductor die 400 illustrated in FIG. 4 is similar to the semiconductor die 300 illustrated in FIG. 3, the same reference numerals are used to refer to the same or liked parts, and its detailed description is omitted herein.

In some embodiments, the semiconductor die 100 may be utilized in a semiconductor package. For example, the semiconductor die 100 may be assembled with other components to form a semiconductor package. In some embodiments, the semiconductor package is a three-dimensional integrated circuit (3D-IC) package. In certain embodiments, the semiconductor package is a system-on-integrated-circuit (SoIC) package, or the like. The manufacturing process of the semiconductor package utilizing the semiconductor die 100 will be described below.

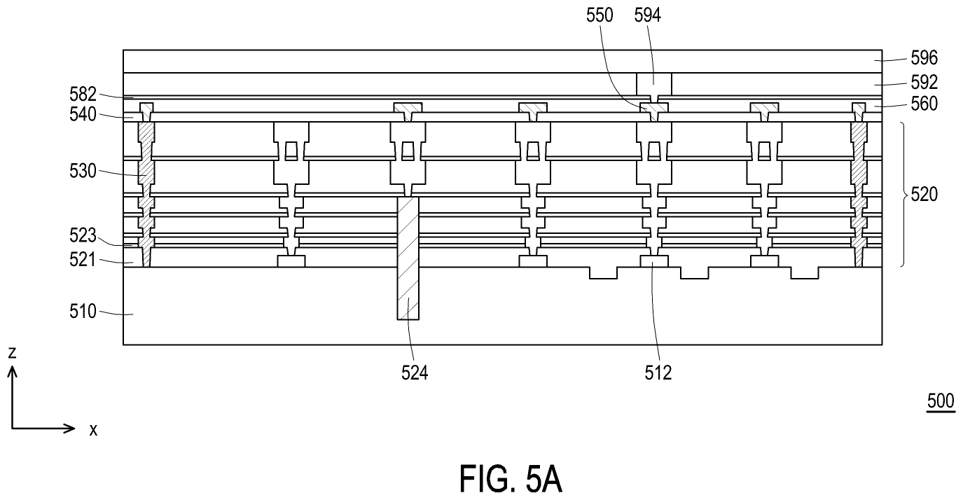

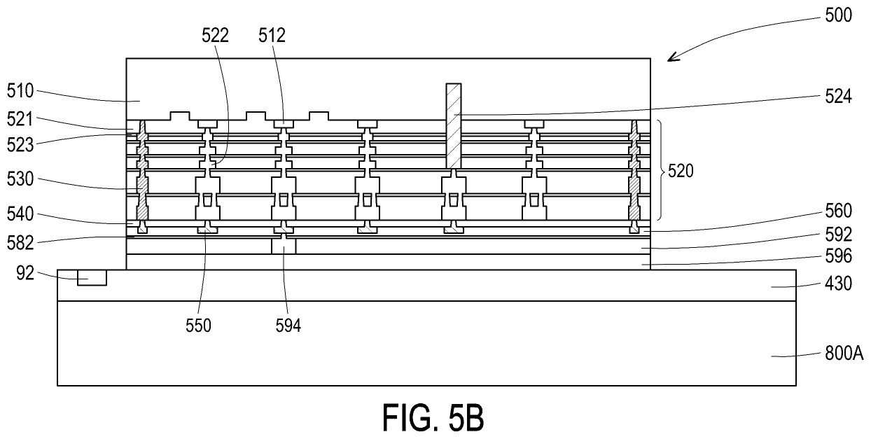

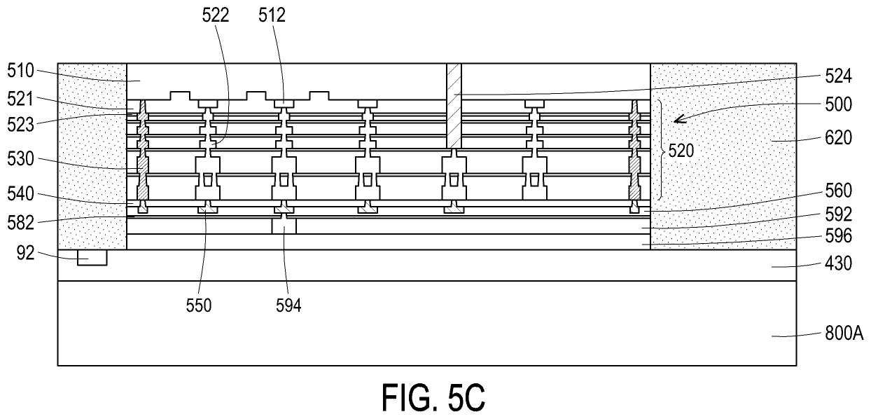

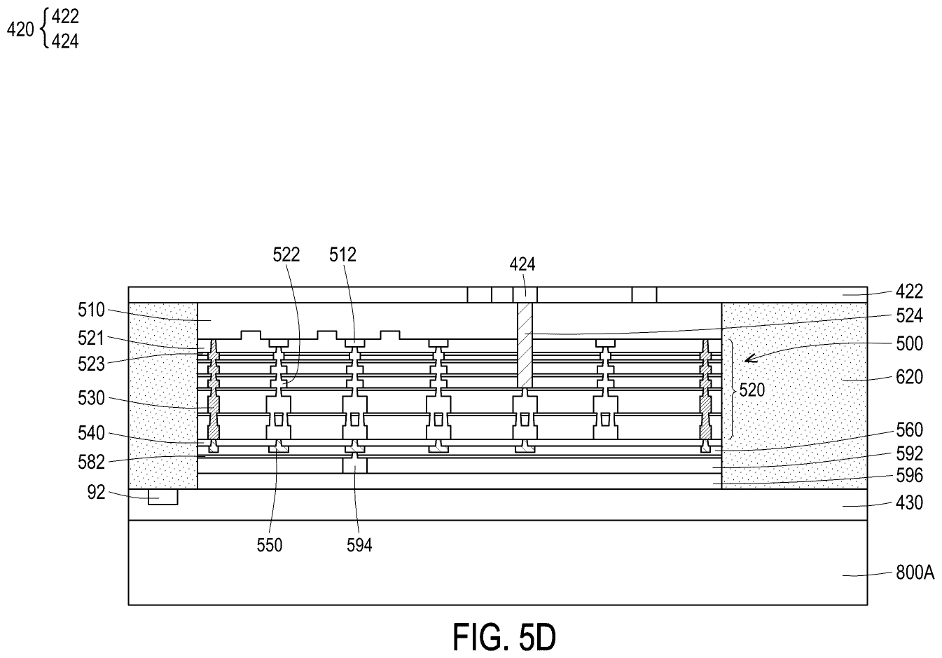

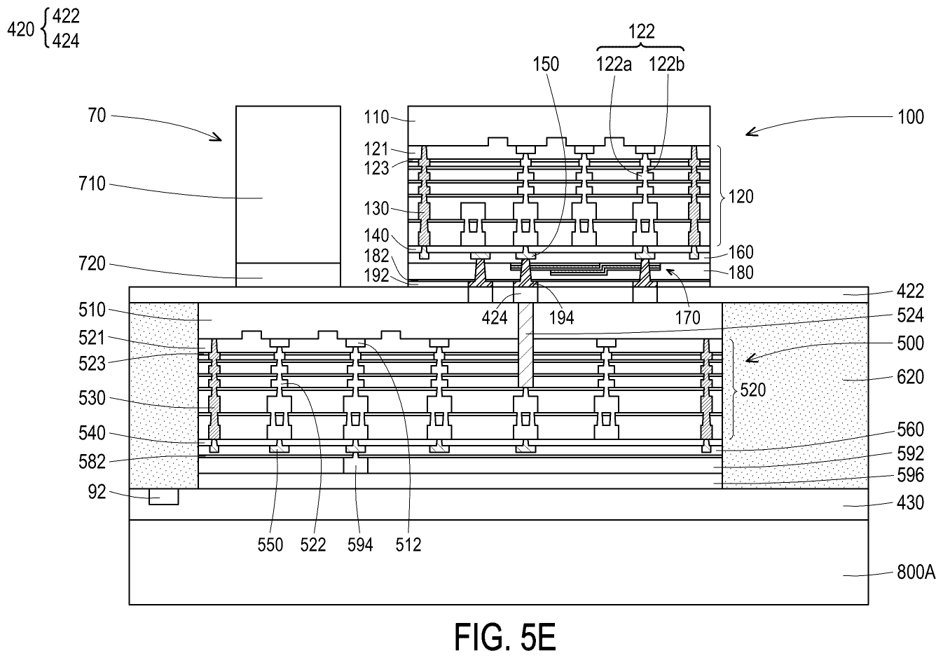

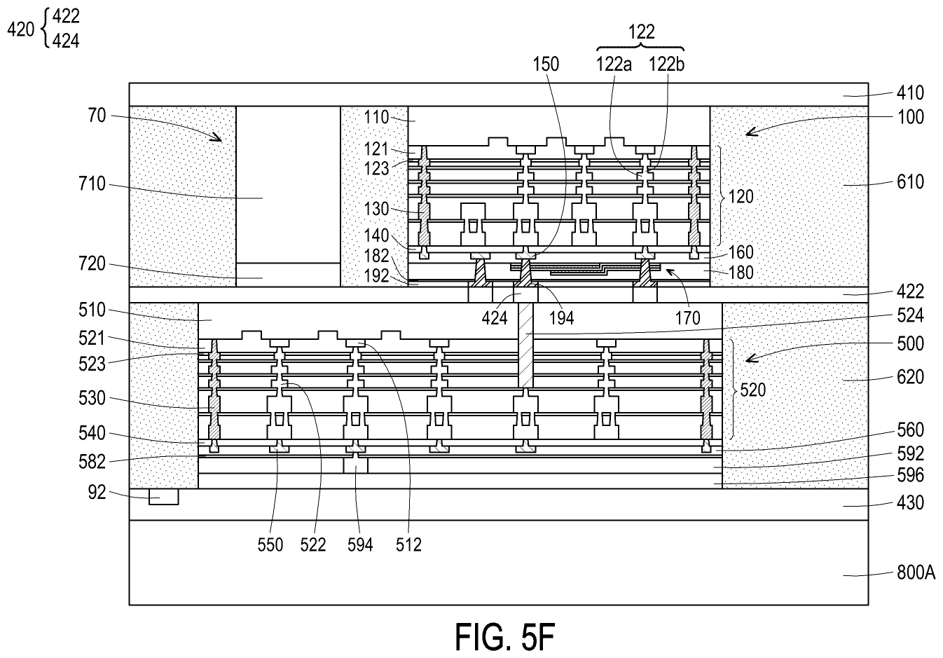

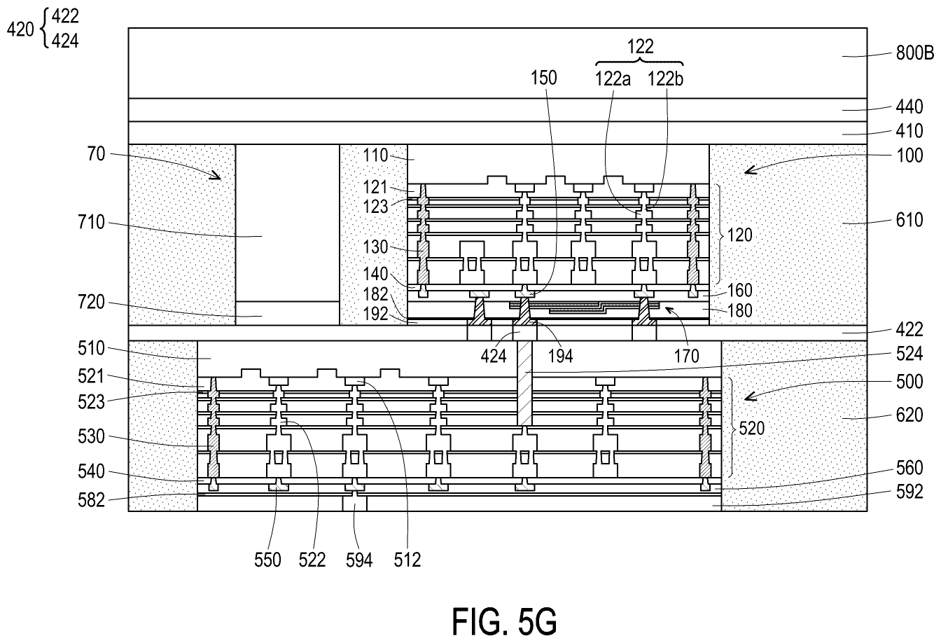

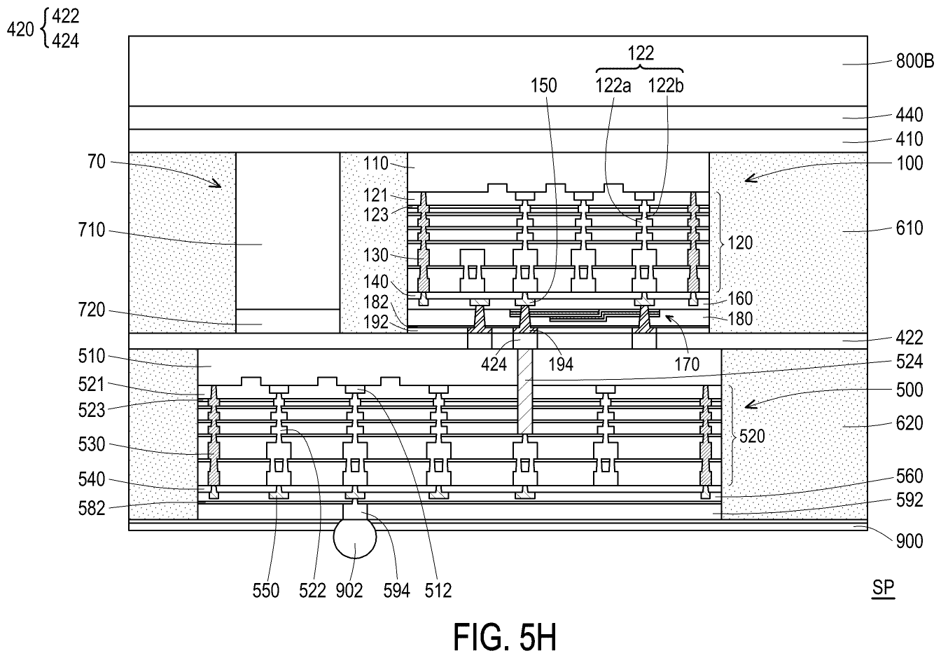

FIG. 5A to FIG. 5H illustrate schematic cross-sectional views of various stages of a manufacturing method of a semiconductor package SP, in accordance with some embodiments of the present disclosure.

Referring to FIG. 5A, a semiconductor substrate 510 is provided. The semiconductor substrate 510 may serve as a carrier for the following layers/components to be formed or disposed thereon. The semiconductor substrate 510 may include one or more devices 512 adjacent to a top surface of the semiconductor substrate 510. The devices 512 may include integrated circuit devices such as transistors, diodes, resistors, capacitors, and/or the like.

Continued referring to FIG. 5A, an interconnection structure 520 is formed on the semiconductor substrate 510, and a conductive via 524 is formed penetrating the interconnection structure 520 to extend into a portion of the semiconductor substrate 510. In some embodiments, the interconnection structure 520 includes a plurality of dielectric layers 521, a plurality of conductive patterns 522, and a plurality of etch stop layers 523, and the conductive patterns 522 are electrically connected to the devices 512. In some embodiments, a seal ring 530 is formed penetrating the interconnection structure 520. In some embodiments, the seal ring 530 is formed by one or more materials the same as the material(s) of the conductive patterns 522. The seal ring 530 functions as a structural supportive element for reinforcing the structural rigidity during dicing or pruning. In some embodiments, the seal ring 530 is an electrically floating element. It is understood that the numbers and configurations of the dielectric layers 521, the etch stop layers 523 and the conductive patterns 522 are merely exemplary and not intended to limit the scope of this disclosure.

Continued referring to FIG. 5A, a passivation layer 540 is formed on the interconnection structure 520. The material of the passivation layer 540 may include silicon oxide, silicon nitride, silicon oxynitride, USG, or the like. Further, referring to FIG. 5A, a redistribution layer 550 is formed penetrating the passivation layer 540 to electrically connect with the interconnection structure 520 and the conductive via 524. In some embodiments, the redistribution layer 150 includes conductive patterns, such as conductive pads and/or conductive wirings. The conductive patterns of the redistribution layer 550 may have a pitch or a line/spacing (L/S) different from that of the conductive patterns 522 of the interconnection structure 520. In some embodiments, the material of the redistribution layer 550 includes copper, aluminum, aluminum copper, or any other suitable conductive materials. In certain embodiments, the material of the redistribution layer 550 includes aluminum or copper-doped aluminum, wherein a doping concentration of copper is 0.001% to about 50%. In an embodiment, the doping concentration of copper is about 0.5%.

Continued referring to FIG. 5A, a gap-filling dielectric layer 560 is formed on the passivation layer 540 and covers the redistribution layer 550. In some embodiments, the gap-filling dielectric layer 560 fills the gaps between the conductive patterns of the redistribution layer 550 for providing a substantially planar top surface. In some embodiments, a planarization process is performed on the gap-filling dielectric layer 560 to provide the substantially planar top surface. The planarization process may include performing a CMP process. In some embodiments, the gap-filling dielectric layer 560 is formed by CVD (such as plasma enhanced CVD, HDPCVD, or MOCVD), or PVD. In some embodiments, the material of the gap-filling dielectric layer 560 may include dielectric materials, such as SiO, SiN, SiON.

Continued referring to FIG. 5A, an etch stop layer 582 and a dielectric layer 592 are formed over the gap-filling dielectric layer 560 in sequence. In some embodiments, the dielectric layer 592 is configured to be hybrid-bonded or fusion-bonded to another dielectric layer. In such embodiments, the dielectric layer 592 is referred to as a bonding dielectric layer. In some embodiments, the dielectric layer 592 includes an oxide based layer. In some embodiments, the dielectric layer 592 includes silicon oxide, silicon oxynitride, or any suitable materials configured for hybrid bonding or fusion bonding. In some embodiments, the dielectric layer 592 includes polymer such as polyimide, benzocyclobutene (BCB), polybenzoxazole (PBO), or the like.

Continued referring to FIG. 5A, a bonding conductor 594 is formed to electrically connect with the redistribution layer 550. The material of the bonding conductor 594 may be or include copper or other suitable conductive materials. Furthermore, in some embodiments, the bonding conductor 594 may optionally include a barrier layer (not shown) at the outer surface, so as to avoid diffusion of atoms between elements. For example, the material of the barrier layer may be or include tungsten (W), titanium nitride (TiN), titanium (Ti), tantalum (Ta), tantalum nitride (TaN), combinations thereof or other suitable materials. It is understood that the number of the bonding conductor 594 is merely exemplary and not intended to limit the scope of this disclosure. That is, more than one bonding conductor 594 may be formed over the redistribution layer 550. In some embodiments, the bonding conductor 594 may be an under bump metallization (UBM) pad for mounting a conductive connector (i.e., bump connector 902 shown in FIG. 5H).

As shown in FIG. 5A, due to the formation of the etch stop layer 582, the bonding conductor 594 may include a bottom portion formed passing through the gap-filling dielectric layer 560 to be physically in contact with the redistribution layer 550, and a top portion formed within the dielectric layer 592 and wider than the bottom portion. However, the disclosure is not limited thereto. In some alternative embodiments, the bonding conductor 594 may be formed as a single portion with a continuous sidewall. Further, as shown in FIG. 5A, the bonding conductor 594 may be exposed by a top surface of the dielectric layer 592.

Continued referring to FIG. 5A, a bonding layer 596 is formed on the dielectric layer 592, and covers the bonding conductor 594. In some embodiments, the bonding layers 596 may include an oxide based layer having oxide based bonding surface.

Continued referring to FIG. 5A, a singulation process is performed along the scribe lines such that a plurality of singulated semiconductor dies 500 are formed. It is noted that, the manufacturing process described above is part of a wafer level packaging process, although one singulated semiconductor die 500 is shown in FIG. 5A, those skilled in the art should understand that plural semiconductor dies 500 are obtained after the singulation process. In some embodiments, the singulation process includes a dicing process or a sawing process. In a subsequent process, the singulated semiconductor die 500 may, for example, be disposed onto a package substrate or onto other components based on requirements.

Referring to FIG. 5B, a carrier 800A is provided, and the semiconductor die 500 is bonded to the carrier 800A. In some embodiments, a bonding layer 430 is formed on the carrier 800A. The bonding layer 430 may include an oxide based layer having an oxide based bonding surface. In some embodiments, the bonding layer 596 is fusion-bonded to the bonding layer 430. An alignment mark 92 may be in the bonding layer 430 prior to bonding the semiconductor die 500 to the carrier 800A. The alignment mark 92 may be free from overlapping the semiconductor die 500 from a top view perspective (i.e., along the direction Z).

Referring to FIG. 5C, a dielectric structure 620 is formed to cover the bonding layer 430 and laterally encapsulate the semiconductor die 500 along the direction X, and the semiconductor substrate 510 is thinned to expose the conductive via 524. In some embodiments, a CMP process may be performed to remove portions of the semiconductor substrate 510, the dielectric structure 620, and the conductive via 524 to expose a portion of the conductive via 524 from a surface of the semiconductor substrate 510. The dielectric structure 620 may be a gap filling dielectric material (e.g., tetraethoxysilane (TEOS) formed oxide material or other suitable dielectric material) formed by a deposition process (e.g., CVD, PVD or other suitable deposition process).

Referring to FIG. 5D, a bonding structure 420 is formed on the semiconductor substrate 510 and the dielectric structure 620. In detail, as shown in 5D, the bonding structure 420 includes a bonding layer 422 and bonding conductors 424 embedded in the bonding layer 422. Further, as shown in FIG. 5D, one of the bonding conductors 424 is formed to connect with the conductive via 524. The bonding layer 422 may include an oxide based layer having an oxide based bonding surface. The bonding conductor 424 may be exposed by a top surface (e.g., the oxide based bonding surface) of the oxide based layer. It is understood that the number of the bonding conductors 424 is merely exemplary and not intended to limit the scope of this disclosure.

Referring to FIG. 5E, the semiconductor die 100 is bonded to the semiconductor die 500. Although FIG. 5 shows the semiconductor die 100 is bonded to the semiconductor die 500, those skilled in the art should understand that the semiconductor dies 200-400 may also be chosen to be bonded to the semiconductor die 500. In some embodiments, the dielectric layer 192 of the semiconductor die 100 is bonded to the bonding layer 422 of the bonding structure 420. In some embodiments, the dielectric layer 192 of the semiconductor die 100 is fusion-bonded to the bonding layer 422. In some embodiments, the bonding conductor 194 of the semiconductor die 100 is physically in contact with and bonded to the bonding conductor 424 of the bonding structure 420. That is, the dielectric layer 192 and the bonding conductor 194 may be collectively referred to as a bonding structure of the semiconductor die 100, and the semiconductor die 100 is bonded to the semiconductor die 500 through the bonding structure 420 and the bonding structure of the semiconductor die 100.

In detail, as shown in FIG. 5E, the bonding interface between the bonding structure 420 and the bonding structure of the semiconductor die 100 includes metallic-to-metallic bonding interface and dielectric-to-dielectric bonding interface, wherein the metallic-to-metallic bonding interface is between the bonding conductor 194 and the bonding conductor 424, and the dielectric-to-dielectric bonding interface is between the dielectric layer 192 and the bonding layer 422. That is, the bonding structure of the semiconductor die 100 is hybrid-bonded with the bonding structure 420.

In some embodiments, as shown in FIG. 5E, a support die 70 may be optionally bonded to the semiconductor die 500. In some embodiments, the support die 70 includes a body portion 710 and a bonding layer 720. The body portion 710 may include a semiconductor substrate including Si, Ge, SiGe, SiC, or other proper semiconductor materials. The body portion 710 may be a bulk substrate or constructed as a semiconductor on an insulator (SOI) substrate. The bonding layer 720 may include an oxide based layer having an oxide based bonding surface. In some embodiments, the bonding layer 720 is fusion-bonded to the bonding layer 422. In some embodiments, the oxide based layer of the bonding layer 720 is fusion-bonded to the oxide based bonding surface of the bonding layer 422. It is noted that by including the support die 70 bonded to the semiconductor die 500, the stress distribution of the resulting semiconductor package SP is more uniform, and the heat dissipation efficiency of the resulting semiconductor package SP is better.

Referring to FIG. 5F, a dielectric structure 610 is formed to cover the bonding layer 422 and laterally encapsulate the semiconductor die 100 and the support die 70, and a bonding layer 410 is formed on the dielectric structure 610, the semiconductor die 100, and the support die 70. The bonding layer 410 may include an oxide based layer having an oxide based bonding surface. The material and process used to form the dielectric structure 610 may be similar to, or the same as, those of the dielectric structure 620, and the details thereof are not repeated herein.

Referring to FIG. 5G, a bonding layer 440 is formed or disposed on the bonding layer 410, and a carrier 800B may be formed or disposed on the bonding layer 440. The bonding layer 440 may include an oxide based layer having an oxide based bonding surface. In some embodiments, the oxide based layer of the bonding layer 440 is fusion-bonded to the oxide based bonding surface of the bonding layer 410. The carrier 800B may be a semiconductor substrate. Continued referring to FIG. 5G, the carrier 800A, the bonding layer 430, the bonding layer 596 and a portion of the dielectric structure 620 are removed to expose the bonding conductor 594.

Referring to FIG. 5H, a passivation layer 900 is formed on the dielectric layer 592 and the bonding conductor 594, and a bump connector 902 is formed penetrating the passivation layer 900 to electrically connect to the bonding conductor 594. As such, the semiconductor package SP is formed. The passivation layer 900 may include silicon oxide, silicon nitride, silicon oxynitride, USG, or the like. The bump connector 902 may be or may include controlled collapse chip connection (C4) bump. It is understood that the number of the bump connector 902 is merely exemplary and not intended to limit the scope of this disclosure. That is, more than one bump connector 902 may be formed over the redistribution layer 550.

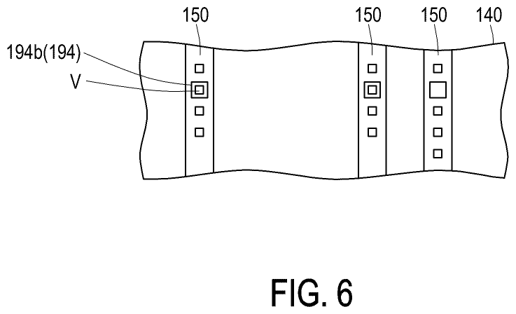

As shown in FIG. 5H, in the semiconductor package SP, the semiconductor die 100 is bonded and electrically connected to the semiconductor die 500 through the bonding conductor 194. That is, the external electrical connection of the semiconductor die 100 can be achieved by the bonding conductors 194. It is noted that in the semiconductor die 100, the arrangement density of the bonding conductors 194 (including the conductive vias 194b), enabling the external electrical connection, is lower than the arrangement density of the conductive patterns (including the vias V) of the redistribution layer 150. That is, as shown in FIG. 6, the open area of the passivation layer 180 (corresponding to the conductive vias 194b) is smaller than the open area of the passivation layer 140 (corresponding to the vias V). In other words, the passivation layer 180 has a lower open density than the passivation layer 140. As such, by arranging the passivation layer 180 with the lower open density, the arrangement area of the capacitor structure 170 embedded in the passivation layer 180 is increased. From another point of view, since the bonding conductor 194 enables the external electrical connection, the bonding conductor 194 belongs to the outermost conductive component of the semiconductor die 100. That is, the exposed surface of the bonding conductor 194 by the top surface of the dielectric layer 192 constitutes a part of the outermost surface of the semiconductor die 100.

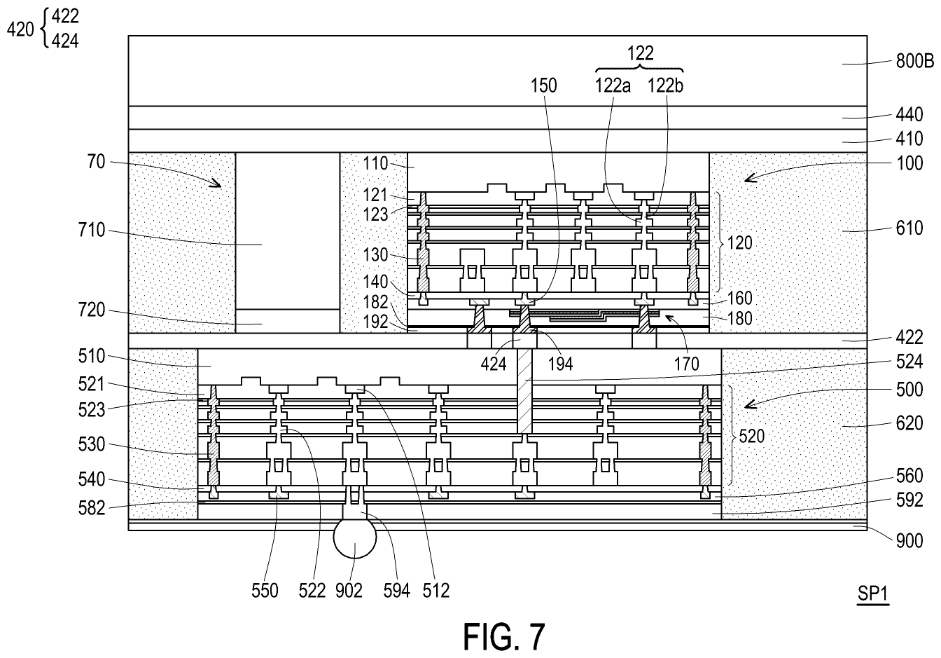

As shown in FIG. 5H, in the semiconductor package SP, the bonding conductor 594 is connected between the redistribution layer 550 and the bump connector 902. However, the disclosure is not limited thereto. In some alternative embodiments, as shown in FIG. 7, in the semiconductor package SP1, the bonding conductor 594 is connected between the conductive patterns 522 of the interconnection structure 520 and the bump connector 902. In detail, as shown in FIG. 7, the bottom portion of the bonding conductor 594 vertically penetrates through the gap-filling dielectric layer 560 and the passivation layer 540 to establish electrical connection with the interconnection structure 520. Since the semiconductor package SP1 illustrated in FIG. 7 is similar to the semiconductor package SP illustrated in FIG. 5H, the same reference numerals are used to refer to the same or liked parts, and its detailed description is omitted herein.

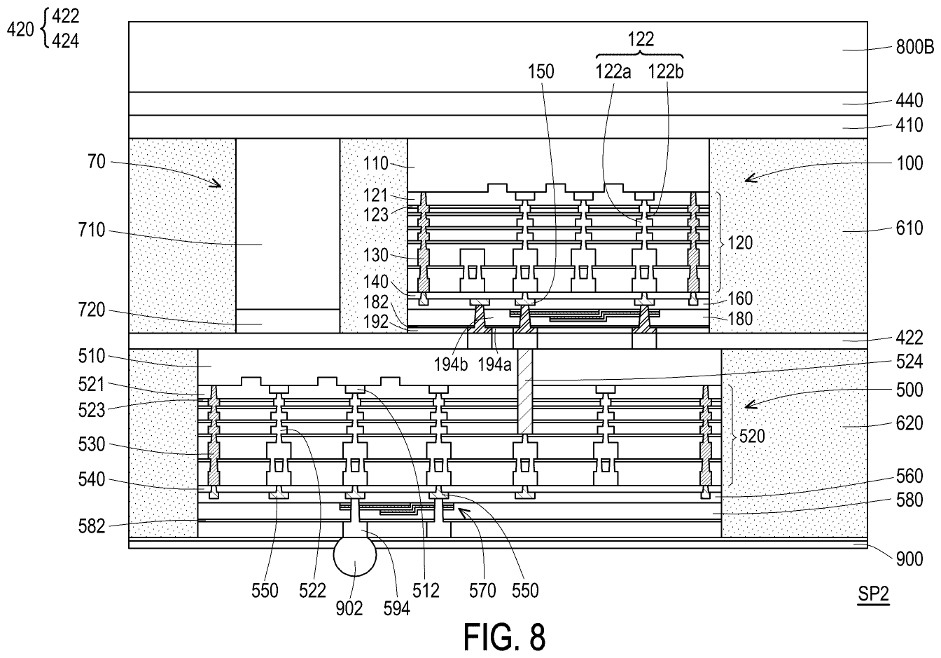

Further, as shown in FIG. 5H, in the semiconductor package SP, there is no capacitor structure in the semiconductor die 500. However, the disclosure is not limited thereto. In some alternative embodiments, as shown in FIG. 8, in the semiconductor package SP2, the semiconductor die 500 includes a capacitor structure 570, and the bonding conductors 594 serve as the electrode connectors of the capacitor structure 570. It is noted that since the bonding conductors 594 made of copper are used as the electrode connectors of the capacitor structure 570, the junction resistance between the capacitor structure 570 and the electrode connectors can be reduced. Thereby, the capacitor efficiency of the capacitor structure 570 is improved. Further, it is noted that for the semiconductor package (SP, SP1, SP2) or the semiconductor die 500, the external electrical connection thereof may be achieved by the bonding conductor 594 of the semiconductor die 500. As such, by using the bonding conductors 594, enabling the external electrical connection, as the electrode connectors of the capacitor structure 570, the capacitance area of the capacitor structure 570 is increased. The capacitor structure 570 may be fabricated in the manner similar to the process described in FIG. 1C to FIG. 1F. In detail, as shown in FIG. 8, the capacitor structure 570 is formed on the gap-filling dielectric layer 560, and is covered by a passivation layer 580. The material and process used to form the passivation layer 580 may be similar to, or the same as, those of the passivation layer 180, and the details thereof are not repeated herein.

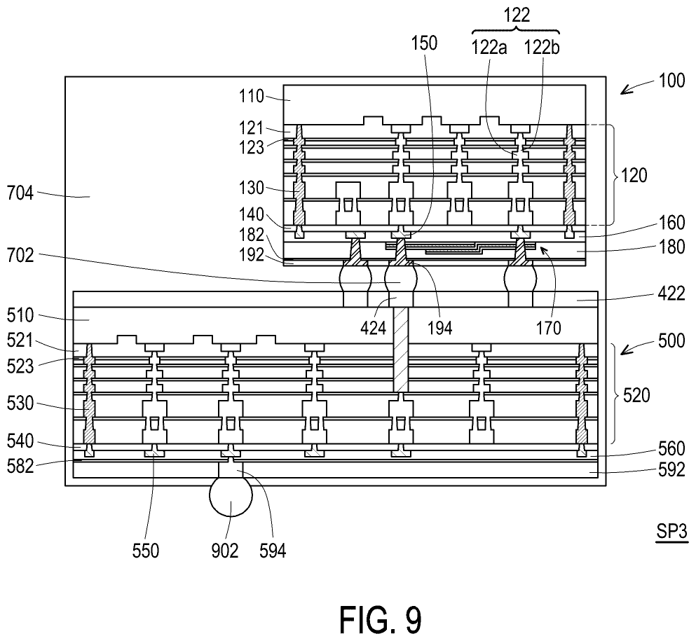

Moreover, as shown in FIG. 5H, FIG. 7 and FIG. 8, in the semiconductor packages SP to SP2, the top die (i.e., semiconductor die 100) and the bottom die (i.e., semiconductor die 500) are bonded with each other via dielectric-dielectric bonding of the dielectric layer 192 and the bonding layer 422, and metallic-to-metallic bonding of the bonding conductor 194 and the bonding conductor 424. That is, the bonding conductor 194 enables the external electrical connection through direct metallic-to-metallic bonding. However, the disclosure is not limited thereto. In some alternative embodiments, the bonding conductor may enable the external electrical connection through joint terminal or metal wiring. Hereinafter, other embodiments will be described with reference to FIG. 9 to FIG. 12.

Referring to FIG. 9, in the semiconductor package SP3, the semiconductor die 100 as the top die is bonded and electrically connected to the semiconductor die 500 as the bottom die through joint terminals 702. For example, the joint terminal 702 is sandwiched between the bonding conductor 194 and the bonding conductor 424 to render electrical connection between the semiconductor die 100 and the semiconductor die 500. In detail, as shown in FIG. 9, the joint terminal 702 is physically in contact with the bonding conductor 194 and the bonding conductor 424. In some embodiments, the joint terminal 702 is solder joint formed by a ball placement process and/or a reflowing process. The joint terminal 702 may be or may include micro-bump, metal pillar, or C4 bump. It is understood that the number of the joint terminals 702 is merely exemplary and not intended to limit the scope of this disclosure.

In some embodiments, as shown in FIG. 9, the semiconductor package SP3 includes a dielectric structure 704 surrounding the semiconductor die 100, the semiconductor die 500 and the joint terminal 702. Further, in some embodiments, as shown in FIG. 9, a portion of the bump connector 902 near the dielectric layer 592 and the bonding conductor 594 is laterally surrounded by the dielectric structure 704. The dielectric structure 704 may be a molding compound formed by a mold injection process or other suitable process.

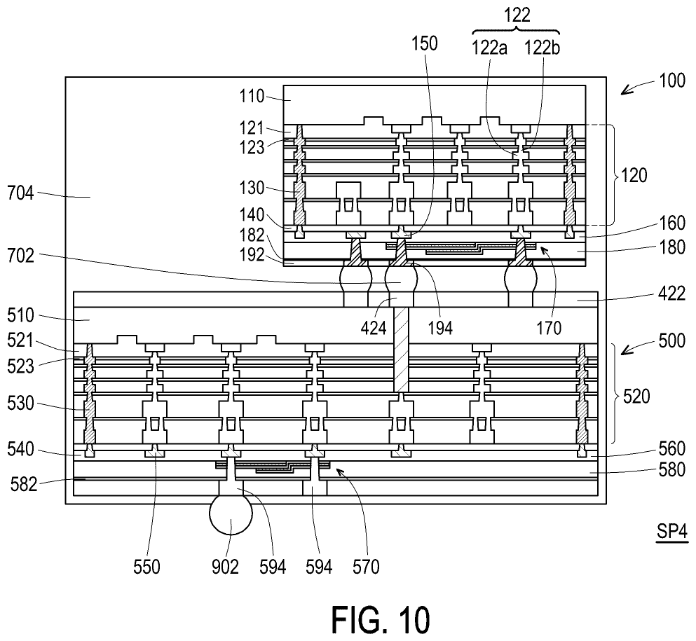

As shown in FIG. 9, in the semiconductor packages SP3, there is no capacitor structure in the semiconductor die 500. However, the disclosure is not limited thereto. In some alternative embodiments, as shown in FIG. 10, in the semiconductor package SP4, the semiconductor die 500 includes the capacitor structure 570 (referred to FIG. 8 descried above), and the bonding conductors 594 serve as the electrode connectors of the capacitor structure 570.

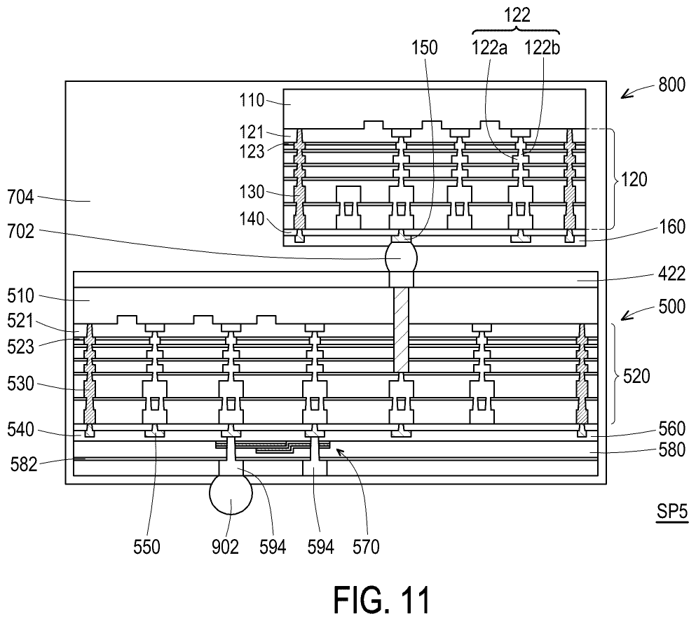

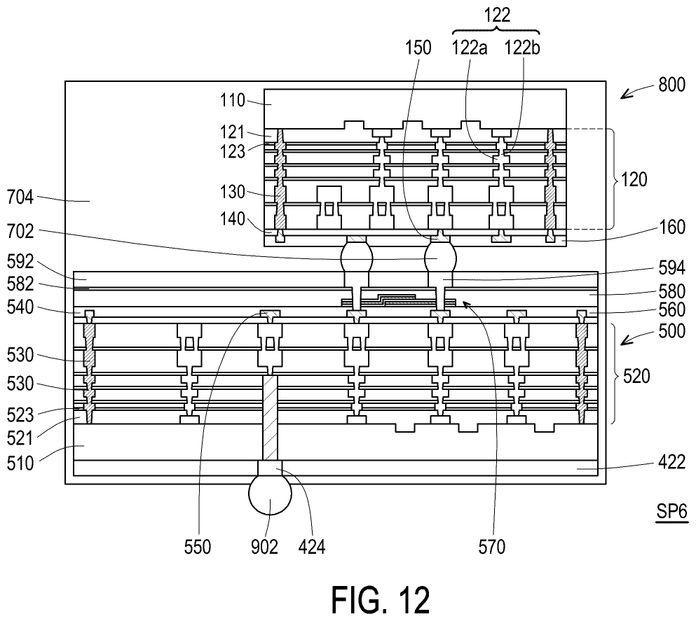

Further, as shown in FIG. 9, in the semiconductor package SP3, only the top die includes the capacitor structure, and as shown in FIG. 10, in the semiconductor packages SP4, both of the top die and the bottom die include the capacitor structure. However, the disclosure is not limited thereto. In some alternative embodiments, in a semiconductor package, the top die may not include a capacitor structure, while the bottom die includes a capacitor structure. Hereinafter, other embodiments will be described with reference to FIG. 11 to FIG. 12.

FIG. 11 is a schematic cross-sectional view of a semiconductor package in accordance with some alternative embodiments of the present disclosure. The semiconductor package SP5 illustrated in FIG. 11 is similar to the semiconductor package SP4 illustrated in FIG. 10, hence the same reference numerals are used to refer to the same or liked parts, and its detailed description will be omitted herein. The differences between the semiconductor package SP5 and the semiconductor package SP4 will be described below.

Referring to FIG. 11, the semiconductor package SP5 includes a semiconductor die 800 as a top die and the semiconductor die 500 as a bottom die. The semiconductor die 800 is similar to the semiconductor package 100 illustrated in FIG. 5H, the same reference numerals are used to refer to the same or liked parts, and its detailed description is omitted herein. The differences between the semiconductor die 800 and the semiconductor die 100 lie in that there is no a capacitor structure in the semiconductor die 800, and the redistribution layer 150 enables the external electrical connection to the semiconductor die 500. That is, the conductive pattern of the redistribution layer 150 may be referred to as a bonding conductor. Further, the semiconductor die 800 is electrically connected to the semiconductor die 500 through the joint terminal 702. For example, the joint terminal 702 is sandwiched between the bonding conductor 424 and the conductive patterns of the redistribution layer 150 to render electrical connection between the semiconductor die 800 and the semiconductor die 500.

As shown in FIG. 11, in the semiconductor packages SP5, the joint terminal 702 is in direct contact with the bonding conductor 424. However, the disclosure is not limited thereto. In some alternative embodiments, as shown in FIG. 12, in the semiconductor packages SP6, the joint terminal 702 is sandwiched between the bonding conductor 594 and the conductive patterns of the redistribution layer 150 to render electrical connection between the semiconductor die 800 and the semiconductor die 500. That is, in the semiconductor packages SP6, the bonding conductor 594 of the semiconductor die 500 enables the external electrical connection to the semiconductor die 800 through the joint terminal 702. On the other hand, in the semiconductor packages SP6, the bump connector 902 is in direct contact and electrically connected with the bonding conductor 424.

In order to increase the capacitance area of the capacitor structure, the above-mentioned embodiments of the present disclosure utilize the bonding conductors, enabling the external electrical connection, as the electrode connectors of the capacitor structure. Further, in order to reduce the junction resistance of the capacitor structure, the above-mentioned embodiments of the present disclosure utilize the bonding conductors, made of copper, as the electrode connectors of the capacitor structure.

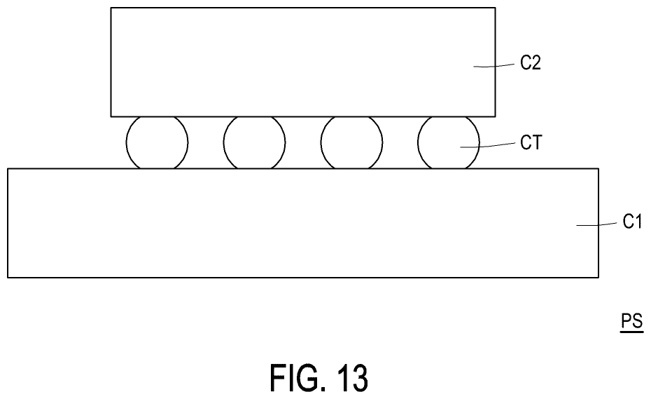

FIG. 13 is a schematic cross-sectional view of a package structure in accordance with some embodiments of the present disclosure. Referring to FIG. 13, a package structure PS including a first component C1 and a second component C2 disposed over the first component C1 is provided. The first component C1 may be or may include an interposer (organic interposer or inorganic interposer), a package substrate, a printed wiring board, a printed circuit board (PCB), and/or other carrier that is capable of carrying integrated circuits. The second component C2 mounted on the first component C1 may be or may include: a logic chip/die (e.g., central processing unit (CPU), graphics processing unit (GPU), Core Chiplet Die (CCD), Input/Output Die (IOD), a memory chip/die (e.g., static random access memory (SRAM)), a passive component (e.g., capacitance, inductance), the like, combinations of these, etc. The second component C2 may be similar to any one of the semiconductor packages described in FIG. 5H and FIG. 7 to FIG. 12. For example, one of the semiconductor packages SP to SP6 may be electrically coupled to the first component C1 through a plurality of terminals CT. The terminal CT may be the bump connector 902 described above. Alternatively, in some embodiments, the terminals CT are terminals having the size greater than the bump connector 902, and a reflow process may be performed on the terminals CT to couple the second component C2 to the first component C1. Further, in some embodiments, more than one the semiconductor packages (e.g., any combination of the semiconductor packages described above) may be arranged side by side and electrically coupled to the first component C1.

In some embodiments, an underfill (not shown) is optionally formed between the gap of the first component C1 and the second component C2 to at least laterally cover the terminals CT. Owing to the underfill, a bonding strength between the first component C1 and the second component C2 is enhanced. The underfill may be any acceptable material, such as a polymer, epoxy resin, molding underfill, or the like, for example. In one embodiment, the underfill may be formed by underfill dispensing, a capillary flow process, or any other suitable method.

Other packaging techniques may be used to form the package structure PS, which are not limited in the disclosure. For example, the package structure PS is formed using a wafer level packaging (WLP), a chip-on-wafer-on-substrate (CoWoS) process, a chip-on-chip-on-substrate (CoCoS) process, an integrated fan-out (InFO) process, etc. The package structure PS may be part of an electronic system for such as computers (e.g., high-performance computer), computational devices used in conjunction with an artificial intelligence system, wireless communication devices, computer-related peripherals, entertainment devices, etc. It should be noted that other electronic applications are also possible.

In accordance with an embodiment, a semiconductor die includes a semiconductor substrate, an interconnect structure, a capacitor structure, a redistribution layer and a bonding conductor. The interconnect structure is disposed on the semiconductor substrate. The capacitor structure is disposed on the interconnect structure. The redistribution layer is disposed on and electrically connected to the interconnect structure. The bonding conductor is electrically and in contact with the capacitor structure at a sidewall of the bonding conductor, wherein the redistribution layer is located at a lower level than the bonding conductor.

In accordance with an embodiment, a semiconductor package includes a first semiconductor die and a second semiconductor die. The second semiconductor die is electrically connected with the first semiconductor die, wherein the second semiconductor die includes a semiconductor substrate, an interconnect structure, a bonding conductor, a redistribution layer and a capacitor structure. The interconnect structure is disposed on the first semiconductor substrate. The bonding conductor is disposed on and electrically connected with the interconnect structure. The redistribution layer is disposed on the interconnect structure at a lower level than the bonding conductor. The capacitor structure laterally surrounds and is electrically connected with a sidewall of the bonding conductor.

In accordance with an embodiment, a method of manufacturing a semiconductor die includes the following processes. An interconnect structure is formed on a semiconductor substrate. A capacitor structure is formed over the interconnect structure. A redistribution layer is formed over and electrically connected to the interconnect structure. A bonding conductor vertically penetrates through the capacitor structure to be electrically connected with the capacitor structure at a sidewall of the bonding conductor, wherein the bonding conductor is formed at a higher level than the redistribution layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
a semiconductor substrate;
an interconnect structure disposed on the semiconductor substrate;
a capacitor structure disposed on the interconnect structure;
a redistribution layer disposed on and electrically connected to the interconnect structure; and
a bonding conductor electrically and in contact with the capacitor structure at a sidewall of the bonding conductor, wherein the redistribution layer is located at a lower level than the bonding conductor.

2. The semiconductor die of claim 1, wherein the bonding conductor lands on and is electrically connected with the interconnect structure.

3. The semiconductor die of claim 1, wherein a material of the redistribution layer is different from a material of the bonding conductor.

4. The semiconductor die of claim 3, wherein the material of the redistribution layer includes aluminum, and the material of the bonding conductor includes copper.

5. The semiconductor die of claim 3, wherein the bonding conductor lands on and is electrically connected with the redistribution layer.

6. The semiconductor die of claim 3, further comprising:
a dielectric layer covering the redistribution layer; and
a passivation layer disposed over the dielectric layer and covering the capacitor structure.

7. The semiconductor die of claim 1, wherein the capacitor structure comprises a first electrode layer, a second electrode layer and a dielectric layer between the first electrode layer and the second electrode layer, and the sidewall of the bonding conductor is electrically and physically in contact with one of the first electrode layer and the second electrode layer.

8. The semiconductor die of claim 1, further comprising:
a dielectric layer laterally surrounding the bonding conductor, wherein the surface of the bonding conductor is exposed by the dielectric layer.

9. A semiconductor package, comprising:
a first semiconductor die; and
a second semiconductor die electrically connected with the first semiconductor die, wherein the second semiconductor die includes:
a semiconductor substrate;
an interconnect structure disposed on the first semiconductor substrate;
a bonding conductor disposed on and electrically connected with the interconnect structure;
a redistribution layer disposed on the interconnect structure at a lower level than the bonding conductor; and
a capacitor structure laterally surrounding and electrically connected with a sidewall of the bonding conductor.

10. The semiconductor package of claim 9, further comprising:
a bonding structure electrically connected with and sandwiched between the first semiconductor die and the second semiconductor die, wherein the bonding structure is physically in contact with the bonding conductor.

11. The semiconductor package of claim 10, wherein
the second semiconductor die further comprises:
a dielectric layer laterally surrounding the bonding conductor of the second semiconductor die, wherein the surface of the bonding conductor of the second semiconductor die is exposed by the dielectric layer; and
the bonding structure comprises:
a bonding conductor; and
a bonding layer laterally surrounding the bonding conductor of the bonding structure, wherein the bonding conductor of the bonding structure is physically in contact with the bonding conductor of the second semiconductor die, and the bonding layer is physically in contact with the dielectric layer.

12. The semiconductor package of claim 10, wherein the bonding structure comprises a joint terminal physically in contact with the bonding conductor of the second semiconductor die.

13. The semiconductor package of claim 9, wherein the first semiconductor die comprises:
a semiconductor substrate;
an interconnect structure disposed on the semiconductor substrate of the first semiconductor die;
a bonding conductor disposed on and electrically connected with the interconnect structure of the first semiconductor die; and
a capacitor structure laterally surrounding and electrically connected with a sidewall of the bonding conductor of the first semiconductor die.

14. The semiconductor package of claim 13, further comprising:
a bump connector physically in contact with the bonding conductor of the first semiconductor die.

15. The semiconductor package of claim 9, wherein the bonding conductor of the second semiconductor die lands on and is electrically connected with the interconnect structure of the second semiconductor die.

16. The semiconductor package of claim 9, wherein a material of the redistribution layer is different from a material of the bonding conductor of the second semiconductor die, and the bonding conductor of the second semiconductor die lands on and is electrically connected with the redistribution layer.

17. The semiconductor package of claim 9, wherein the capacitor structure of the second semiconductor die comprises a first electrode layer, a second electrode layer and a dielectric layer between the first electrode layer and the second electrode layer, and the sidewall of the bonding conductor of the second semiconductor die is electrically and physically in contact with one of the first electrode layer and the second electrode layer.

18. A method of manufacturing a semiconductor die, comprising:
forming an interconnect structure on a semiconductor substrate;
forming a capacitor structure over the interconnect structure;
forming a redistribution layer over and electrically connected to the interconnect structure; and
forming a bonding conductor vertically penetrating through the capacitor structure to be electrically connected with the capacitor structure at a sidewall of the bonding conductor, wherein the bonding conductor is formed at a higher level than the redistribution layer.

19. The method of claim 18, wherein the redistribution layer is formed before forming the capacitor structure, and a material of the redistribution layer is different from a material of the bonding conductor.

20. The method of claim 18, further comprising:
forming a passivation layer covering the capacitor structure,
wherein the redistribution layer is formed to pass through the passivation layer and electrically connected to the interconnect structure, and a material of the redistribution layer is different from a material of the bonding conductor.
